(19) United States
(12) Patent Application Publication
(10) Pub. No.: US 2026/0221066 A1
(43) Pub. Date: Jul. 30, 2026

(54) DISPLAY MODULE AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Kejin Song, Beijing (CN); Jing Wang, Beijing (CN); Mingzhou Guo, Beijing (CN); Wei Gao, Beijing (CN); Guoyan Liu, Beijing (CN); Wenfeng Guo, Beijing (CN); Guangjie Yang, Beijing (CN); Chengyi Li, Beijing (CN); Xiaozhong Xue, Beijing (CN); Jie Zeng, Beijing (CN); Xiaoyu Tang, Beijing (CN); Hongdou Zhao, Beijing (CN); Hao Chen, Beijing (CN); Youzhi Zhang, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/151,720

(22) PCT Filed: Jun. 14, 2024
(86) PCT No.: PCT/CN2024/099406

§ 371 Date: Jul. 29, 2025

(30) Foreign Application Priority Data
Jul. 24, 2023 (CN) 202310913590.6

(51) Int. Cl. G09G 3/3225; G06F 1/16; H04B 5/48; H10K 59/80; H10K 102/00; H10W 42/60

(52) U.S. Cl. CPC G09G 3/3225; G06F 1/163; G06F 1/1652; H04B 5/48; H10K 59/8794; H10W 42/60; G09G 2320/0247; G09G 2330/045; G09G 2330/06; H10K 2102/311

(57) ABSTRACT

Provided are a display module and a display device. The display module includes: a display panel including a light-emitting side and a backlight side arranged opposite to each other; a Near Field Communication (NFC) module located on the backlight side of the display panel; and an electrostatic shielding layer located on the backlight side of the display panel, the electrostatic shielding layer includes a first hollowed-out region, an orthogonal projection of the first hollowed-out region on the display panel and an orthogonal projection of the NFC module on the display panel at least partially overlap with each other.

### CROSS-REFERENCE TO RELATED APPLICATIONS

The present application claims priority to Chinese patent application No. 202310913590.6, entitled “DISPLAY MODULE AND DISPLAY DEVICE”, filed on Jul. 24, 2023 before the China National Intellectual Property Administration, which is incorporated herein in its entirety by reference.

### TECHNICAL FIELD

This disclosure relates to the field of display technology, in particular to a display module and a display device.

### BACKGROUND

Some display devices are equipped with a Near Field Communication (NFC) module to enable functions such as mobile payment, electronic ticketing, access control, and mobile identity verification. During use, the display devices with an NFC module are prone to display defects such as screen flickering and water ripples.

### SUMMARY

The embodiments of this disclosure provide a display module and a display device that improve display defects such as screen flickering and water ripples while ensuring the normal operation of the Near Field Communication (NFC) module.

To achieve the above objectives, the embodiments of this disclosure adopt the following technical solutions.

An aspect provides a display module, including: a display panel including a light-emitting side and a backlight side arranged opposite to each other; a Near Field Communication (NFC) module located on the backlight side of the display panel; and an electrostatic shielding layer located on the backlight side of the display panel, wherein the electrostatic shielding layer includes a first hollowed-out region, an orthogonal projection of the first hollowed-out region on the display panel and an orthogonal projection of the NFC module on the display panel at least partially overlap with each other.

In some embodiments, the electrostatic shielding layer further includes an electrostatic shielding region surrounding the first hollowed-out region, the orthogonal projection of the NFC module on the display panel is within the orthogonal projection of the first hollowed-out region on the display panel.

In some embodiments, the display panel includes a center region and a peripheral region surrounding the center region, an orthogonal projection of the electrostatic shielding region on the display panel at least partially covers the peripheral region.

In some embodiments, the display module further includes a heat dissipation layer coupled to the backlight side of the display panel, and the electrostatic shielding layer is coupled to a side of the heat dissipation layer facing away from the display panel.

In some embodiments, the heat dissipation layer is provided with a groove, the groove is arranged opposite to the first hollowed-out region, and the groove and the first hollowed-out region enclose an accommodating recess, at least a part of structures of the NFC module is located within the accommodating recess.

In some embodiments, a depth of the accommodating recess in a direction perpendicular to the display panel is greater than or equal to a thickness of the NFC module in the direction perpendicular to the display panel.

In some embodiments, the electrostatic shielding layer is located on a side of the NFC module facing away from the display panel.

In some embodiments, the heat dissipation layer includes a thermal conductive layer and an adhesive layer stacked in sequence in a direction facing away from the display panel, the adhesive layer includes a second hollowed-out region, the second hollowed-out region and the thermal conductive layer enclose the groove.

In some embodiments, the display module further includes a control board. The control board is located on a side of the NFC module facing away from the display panel, and the NFC module is fixedly connected to the control board.

In some embodiments, a side of the control board facing the display panel is in contact with the electrostatic shielding layer.

In some embodiments, a buffer layer is provided between the NFC module and the control board, the buffer layer is bonded to both the NFC module and the control board.

In some embodiments, the display panel is a flexible display panel including a flat portion, a bending portion, and a bonding portion connected in sequence, the bonding portion is bent to the backlight side of the flat portion through the bending portion, the heat dissipation layer is coupled to the backlight side of the flat portion, the electrostatic shielding layer is connected to a side of the heat dissipation layer facing away from the flat portion; the display module further includes a spacer located between the bonding portion and the electrostatic shielding layer.

In some embodiments, the display module further includes a drive chip and a conductive layer. The drive chip is bonded to a side of the bonding portion facing away from the flat portion, the conductive layer covers the drive chip.

Another aspect provides a display module, including: a display panel including a light-emitting side and a backlight side arranged opposite to each other; a heat dissipation layer coupled to the backlight side of the display panel, the heat dissipation layer including a first region and a second region surrounding the first region; an electrostatic shielding layer located on a side of the heat dissipation layer facing away from the display panel, and an orthogonal projection of the electrostatic shielding layer on the heat dissipation layer is within the second region; and a Near Field Communication (NFC) module, wherein at least a part of an orthogonal projection of the NFC module on the heat dissipation layer is within the first region.

Another aspect provides a display device including the display module described above.

### BRIEF DESCRIPTION OF THE DRAWINGS

In order to describe technical solutions of the embodiments of the present disclosure or the related art more clearly, the accompanying drawings used in the illustration of the embodiments or the related art will be briefly introduced. Apparently, the accompanying drawings in the following explanation illustrate merely some embodiments of the present disclosure, and those skilled in the art may obtain other accompanying drawings based on these accompanying drawings without paying any creative effort.

FIG. 1 schematically shows a front view structure of a display device;

FIG. 2 is a schematic front view of a display module;

FIG. 3 is a schematic rear view of a display module;

FIG. 4 is a schematic exploded view of a display module illustrating partial structures;

FIG. 5 schematically shows a scenario where a display device performs Near Field Communication (NFC);

FIG. 6 is a schematic rear view of an NFC module;

FIG. 7 is a schematic cross-sectional view of a coil of the NFC module;

FIG. 8 is a schematic rear view of an electrostatic shielding layer;

FIG. 9 is a rear view of a display module schematically illustrating partial structures;

FIG. 10 is a rear view schematically illustrating another electrostatic shielding layer and another NFC module;

FIG. 11 is a rear view schematically illustrating another electrostatic shielding layer and another NFC module;

FIG. 12 is a cross-sectional view of a display module schematically illustrating partial structures;

FIG. 13 is a rotated cross-sectional view taken along line A-A in FIG. 3;

FIG. 14 is a schematic structural diagram of a control board;

FIG. 15 is a cross-sectional view of another display module schematically illustrating partial structures;

FIG. 16 is a schematic rear view of a heat dissipation layer; and

FIG. 17 is a schematic rear view of a display panel.

### REFERENCE NUMERALS

100—Display module; 200—Housing; 300—Wristband;
110—Cover plate; 120—Display panel; 130—Heat dissipation layer; 140—Conductive layer; 150—Electrostatic shielding layer; 160—NFC module; 170—Spacer; 180—Drive chip; 190—Control board;
121—Flat portion; 122—Bending portion; 123—Bonding portion; 120a—Center region; 120b—peripheral region;
101—Optical adhesive layer; 102—Polarizer; 104—Protective film;
131—Thermal conductive layer; 132—Adhesive layer; 133—Groove; 130a—First region; 130b—Second region;
161—Connection part; 162—Antenna;
151—Electrostatic shielding region; 152—First hollowed-out region;
191—Connector; 192—Bonding end; 193—Connection end

### DETAILED DESCRIPTION

A clear and thorough description for solutions in the embodiments of the present disclosure will be given below in conjunction with the accompanying drawings in the embodiments of the present disclosure. Apparently, the described embodiments are a part of embodiments of the present disclosure, not all the embodiments. All other embodiments obtained, based on the embodiments in the present disclosure, by those skilled in the art without paying creative effort fall within the protection scope of the present disclosure.

In the embodiments of this disclosure, terms such as “first,” “second,” “third,” and “fourth” are used to distinguish identical or similar items with basically the same functions and roles, only for the purpose of clearly describing the technical solutions of the embodiments of this disclosure. These terms should not be interpreted as indicating or implying relative importance or the number of technical features indicated.

In the embodiments of this disclosure, the term “a plurality of” means two or more, and “at least one” means one or more, unless otherwise specifically limited.

In the embodiments of this disclosure, terms such as “upper” and “lower” refer to the orientation or positional relationships based on the orientation or positional relationships shown in the drawings. These terms are used only for the convenience of describing this disclosure and simplifying the description, and should not be understood as indicating or implying that the devices or components referred to must have a specific orientation, be constructed and operated in a specific orientation, and therefore should not be interpreted as limiting this disclosure.

FIG. 1 schematically shows a front view structure of a display device. As shown in FIG. 1, some embodiments of this disclosure provide a display device, which can be any device capable of displaying text or graphics either in the form of moving (e.g., video) or still (e.g., static images) content. More specifically, the embodiments are expected to be implemented in or associated with various electronic devices, such as (but not limited to) mobile phones, wireless devices, personal digital assistants (PDAs), handheld or portable computers, GPS receivers/navigators, cameras, MP4 video players, camcorders, gaming consoles, watches, clocks, calculators, television monitors, flat panel displays, computer monitors, automotive displays (e.g., odometer displays), navigation devices, cockpit controllers and/or displays, camera view displays (e.g., displays for rearview cameras in vehicles), electronic photo frames, electronic billboards or signboards, projectors, architectural structures, packaging, and aesthetic structures (e.g., displays for images of jewelry). In FIG. 1, the display device is exemplarily shown as a smartwatch. It can be understood that, besides smartwatches, the display device can also be other wearable devices with a display module.

Continuing to refer to FIG. 1, the display device may include a display module 100, a housing 200, and a wristband 300. The display module 100 is installed inside the housing 200, and the wristband 300 is connected to the housing 200. When in use, the wristband 300 and the housing 200 are connected to form a loop to be worn on the user's wrist.

For example, the housing 200 is further provided with a motherboard and a battery. The motherboard is electrically connected to the display module 100 to provide image signals to the display module 100, and the battery is electrically connected to the motherboard to supply power to both the motherboard and the display module 100. In practical applications, the display device may also include other modules according to actual usage requirements. For example, the housing 200 may also include a wireless charging coil electrically connected to the motherboard. The wireless charging coil is used in conjunction with a wireless charging base to charge the battery wirelessly.

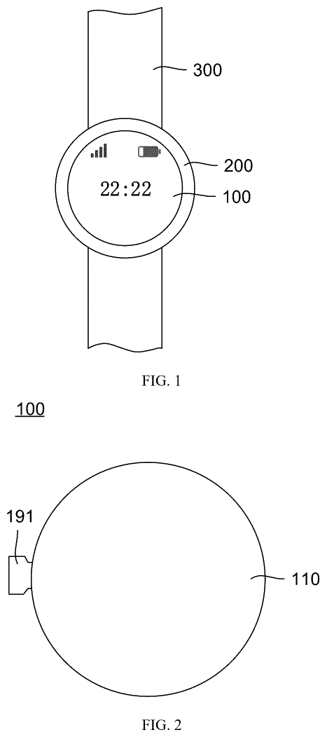

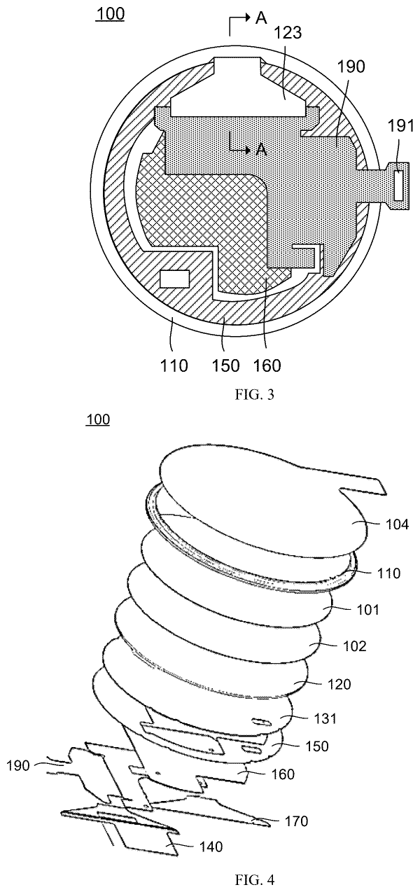

FIG. 2 schematically shows a front view of the display module, FIG. 3 schematically shows a rear view of the display module, and FIG. 4 schematically shows a partial exploded view of the display module. The front view shows the structure of the display module 100 at the light-emitting side, while the rear view shows the structure of the display module 100 at the backlight side.

As shown in FIG. 4, the display module 100 includes a display panel 120. The display panel 120 can be a Liquid Crystal Display (LCD). Alternatively, the display panel 120 can be an electroluminescent display panel or a photoluminescent display panel. When the display panel 120 is an electroluminescent display panel, it can be an Organic Light-Emitting Diode (OLED) display panel, a Quantum Dot Light Emitting Diode (QLED) display panel, or a Micro Light Emitting Diode (Micro LED) display panel and the like. When the display panel 120 is a photoluminescent display panel, it can be a Quantum Dot photoluminescent display panel. Some embodiments of this disclosure illustrate the display panel 120 as an OLED display panel.

The display panel 120 includes a light-emitting side and backlight side arranged oppose to each other. The light-emitting side refers to the side of the display panel 120 from which light is emitted, i.e., the side facing the user when the user views the display panel 120. The backlight side refers to the side of the display panel 120 that is opposite to the light-emitting side, i.e., the side facing away from the user when the user views the display panel 120.

Continuing to refer to FIG. 2 to FIG. 4, the display module 100 can also include a cover plate 110 located on the light-emitting side of the display panel 120. The cover plate 110 is configured to protect the display panel 120 and prevent it from being scratched. The cover plate 110 can be a rigid cover plate or a flexible cover plate, and can be a single-layer structure or a multi-layer structure formed by stacking multiple films. When the display module 100 is a flexible display module, the cover plate 110 is a flexible cover plate. For example, when the cover plate 110 has a single-layer structure, it can be a thin glass cover plate, or it can be a single layer of PI (Polyimide) or a single layer of PET (Polyethylene Terephthalate) or other single-layer transparent polymer layers. When the cover plate 110 has a multi-layer structure, in the direction away from the display panel 120, the cover plate 110 includes a first organic layer, an ultra-thin glass layer, and a second organic layer stacked in sequence, with adjacent layers bonded by optical adhesive. The first organic layer and the second organic layer are made of transparent organic materials.

Continuing to refer to FIG. 4, a protective film 104 can be provided on a side of the cover plate 110 facing away from the display panel 120. The protective film 104 is attached to the surface of the cover plate 110 to protect the cover plate 110 during the assembly of the display module 100 into the display device, preventing the cover plate 110 from being scratched. The protective film 104 can be removed after the display device is assembled. For example, the protective film 104 can be made of an organic material with good light transmittance (such as acrylic).

A polarizer 102 can also be provided between the cover plate 110 and the display panel 120. For example, the polarizer 102 is a circular polarizer capable of filtering out light waves except those perpendicular to the display panel 120, thereby improving the clarity of the display panel 120.

An optical adhesive layer 101 can also be provided between the polarizer 102 and the cover plate 110 for bonding the cover plate 110 to the polarizer 102. For example, the optical adhesive layer 101 is made of an optical resin adhesive (T-OCA) with good light transmittance.

Continuing to refer to FIG. 3 and FIG. 4, the display module 100 also includes a Near Field Communication (NFC) module 160 located on the backlight side of the display panel 120. The NFC module 160 is a module capable of performing near-field communication. Near-field communication is a short-range, high-frequency radio communication technology. For example, near-field communication operates within a communication distance of 10 centimeters, utilizes a frequency of 13.56 MHz, and supports transmission speeds of 106 Kbit/s, 212 Kbit/s, or 424 Kbit/s. The working modes of near-field communication include a passive mode and an active mode. In the passive mode, the master device provides a RF field, and the slave device receives the RF field and converts it into an electrical signal based on the RF field, thereby completing data transmission from the master device to the slave device. In the active mode, the master device provides a RF field, and the slave device receives the RF field and converts it into an electrical signal based on the RF field, thereby completing data transmission from the master device to the slave device; at the same time, the slave device provides a RF field, the master device receives the RF field, and converts it into an electrical signal based on the RF field, thereby completing data transmission from the slave device to the master device.

In the embodiments of this disclosure, the working mode of the NFC module 160 can be the passive mode or the active mode. In other words, the display device can act as either the master device or the slave device in near-field communication. FIG. 5 schematically shows a scenario where the display device performs near-field communication. As shown in FIG. 5, the display device acts as a slave device in near-field communication, receiving the RF field from the master device RFID.

FIG. 5 illustrates a scenario in which the light-emitting side of the display module 100 faces the master device during near-field communication. The master device is an RFID (Radio Frequency Identification) device. In actual applications, it is also possible for the backlight side of the display module 100 to face the master device RFID, which is not limited here. For the sake of description, the following description provides an illustrative example where, during near-field communication, the light-emitting side of the display module 100 faces the master device RFID.

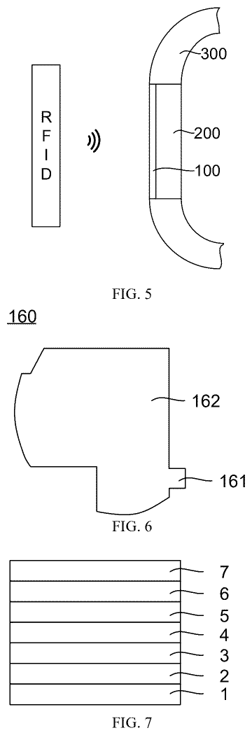

FIG. 6 is a schematic rear view of the Near Field Communication (NFC) module. As shown in FIG. 6, the NFC module 160 can include an antenna 162 and a connection part 161. The antenna 162 includes a plurality of conductive coils that can receive the RF field and convert it into electrical signals based on the received RF field. The connection part 161 is configured to electrically connect the antenna 162 to an external circuit (e.g., control board 190), so that electrical signals generated by the antenna 162 can be transmitted to the external circuit.

FIG. 7 is a schematic cross-sectional view of the coil of the NFC module. For example, as shown in FIG. 7, the NFC module 160 includes an adhesive layer 1, a first mask layer 2, a first wiring layer 3, a substrate layer 4, a second wiring layer 5, a second mask layer 6, and a barrier layer 7. The adhesive layer 1 is used for bonding the NFC module 160 to other structures or layers of the display module 100, thereby securing the NFC module 160. The substrate layer 4 is used for supporting and connecting the first wiring layer 3 and the second wiring layer 5, and the material of the substrate layer 4 can be PI (Polyimide). The first wiring layer 3 and the second wiring layer 5 are used for forming a plurality of conductive coils, and these layers can be patterned copper films. The first mask layer 2 and the second mask layer 6 are masks used for wiring. The barrier layer 7 can be made of anti-oxidation and magnetic shielding materials such as ferrous salts.

It should be understood that the shape and cross-sectional structure of the NFC module 160 shown in FIG. 6 and FIG. 7 are only illustrative, and this disclosure does not limit the structure and shape of the NFC module 160.

Existing display devices equipped with near-field communication (NFC) modules often experience display malfunctions during use. For example, when a display device has a wireless charging coil and is being charged wirelessly through this coil, it is prone to display defects such as water ripples. Additionally, after undergoing electrostatic discharge (ESD) testing, the display device is prone to screen flickering defects.

The inventors have found that the reason for these display defects in existing display devices is the removal of copper foil. Specifically, in order to prevent the copper foil from interfering with or shielding the signals of the NFC module, the copper foil is removed from existing display devices. Since the copper foil is removed, static charges accumulate inside the display device and enter the interior of the display panel along edges of the display panel, causing the characteristics of the transistors inside the display panel to shift and resulting in screen flickering defects. In addition, without the copper foil, it is impossible to shield the electromagnetic field generated during the wireless charging of the display device, causing the display panel to be disturbed by the electromagnetic field and resulting in water ripples defects.

In view of this, the display module 100 of this disclosure includes an electrostatic shielding layer 150. The electrostatic shielding layer 150 can absorb static charges, thereby preventing static charges from entering the interior of the display panel 120 along edges of the display panel and improving display defects such as screen flickering. Additionally, when the display device is wirelessly charged through the wireless charging coil, the electrostatic shielding layer 150 can shield the electromagnetic field generated by the wireless charging coil, preventing the display panel 120 from experiencing water ripples defects.

The electrostatic shielding layer 150 can be made of conductive materials (e.g., metals). For example, the electrostatic shielding layer 150 can be a copper foil with a thickness of 35um.

The electrostatic shielding layer 150 can be arranged in parallel to the light-emitting surface of the display panel 120 and located on the backlight side of the display panel 120. The electrostatic shielding layer 150 can be placed either between the NFC module 160 and the display panel 120 or on the side of the NFC module 160 facing away from the display panel 120. For example, when the master device providing the RF field is located on the light-emitting side of the display panel 120, the electrostatic shielding layer 150 is placed on the side of the NFC module 160 facing away from the display panel 120. When the master device providing the RF field is located on the backlight side of the display panel 120, the electrostatic shielding layer 150 is placed between the NFC module 160 and the display panel 120.

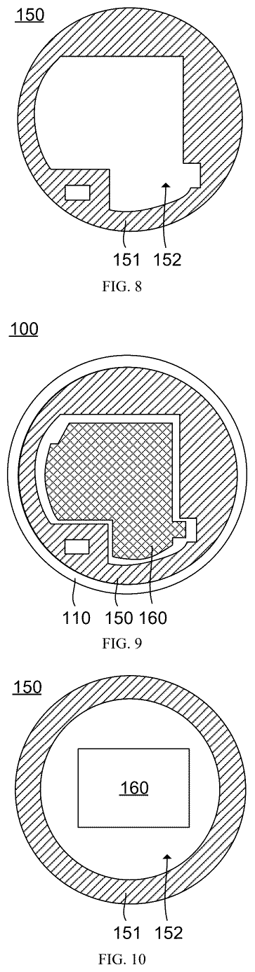

FIG. 8 is a schematic rear view of the electrostatic shielding layer. As shown in FIG. 8, the electrostatic shielding layer 150 includes a first hollowed-out region 152. The first hollowed-out region 152 is a part of the electrostatic shielding layer 150 where the conductive material has been removed. An orthogonal projection of the first hollowed-out region 152 and an orthogonal projection of the NFC module 160 on the display panel 120 at least partially overlap with each other. In other words, at least a part of the first hollowed-out region 152 is arranged directly opposite to the NFC module 160. Since the conductive material has been removed from the first hollowed-out region 152, the part of the electrostatic shielding layer 150 that is directly opposite to the NFC module 160 does not contain conductive material and will not interfere with or shield the RF field, allowing the RF field to pass through the first hollowed-out region 152 and be received by the NFC module 160.

The orthogonal projection of the first hollowed-out region 152 and the orthogonal projection of the NFC module 160 on the display panel 120 can partially overlap or completely overlap with each other. When the orthogonal projection of the first hollowed-out region 152 and the orthogonal projection of the NFC module 160 on the display panel 120 completely overlap with each other, it might mean that the orthogonal projection of the NFC module 160 on the display panel 120 is within the orthogonal projection of the first hollowed-out region 152 on the display panel 120, thereby further reducing the interference and shielding effects of the electrostatic shielding layer 150 on the RF field.

The display module 100 provided in the embodiments of this disclosure includes an electrostatic shielding layer 150 and an NFC module 160 arranged on the backlight side of the display panel 120. The electrostatic shielding layer 150 includes a first hollowed-out region 152, and the orthogonal projection of the first hollowed-out region 152 and the orthogonal projection of the NFC module 160 on the display panel 120 at least partially overlap with each other. Since the conductive material has been removed from the first hollowed-out region 152, the first hollowed-out region 152 will not interfere with or shield the RF field, allowing the RF field to pass through the first hollowed-out region 152 and be received by the NFC module 160. Moreover, the electrostatic shielding layer 150 can absorb static charges, thereby preventing them from entering the interior of the display panel 120 along edges of the display panel 120 and improving display defects such as screen flickering. When the display device is wirelessly charged through the wireless charging coil, the electrostatic shielding layer 150 can shield the electromagnetic field generated by the wireless charging coil, preventing the display panel 120 from experiencing display defects such as water ripples. That is, the display module 100 of this disclosure improves display defects such as screen flickering and water ripples while ensuring the normal communication of the NFC module 160.

Referring again to FIG. 8, the electrostatic shielding layer 150 also includes an electrostatic shielding region 151 surrounding the first hollowed-out region 152. The orthogonal projection of the NFC module 160 on the display panel 120 is within the range of the orthogonal projection of the first hollowed-out region 152 on the display panel 120. The electrostatic shielding region 151 is a part of the electrostatic shielding layer 150. The electrostatic shielding region 151 contains the conductive material, enabling it to absorb static charges and shield against at least some electromagnetic interference. For example, when the electrostatic shielding layer 150 is made of copper foil, the hollowed-out part of the copper foil is the first hollowed-out region 152, and the part that is not hollowed out is the electrostatic shielding region 151.

FIG. 9 is a rear view of a display module schematically illustrating partial structures. For example, as shown in FIG. 9, the shape of the first hollowed-out region 152 can be the same as or similar to that of the NFC module 160. This not only reduces the interference and shielding effects of the electrostatic shielding layer 150 on the RF field, but also increases the area of the electrostatic shielding region 151, thereby enhancing the static charge absorption and electromagnetic interference shielding capabilities of the electrostatic shielding layer 150.

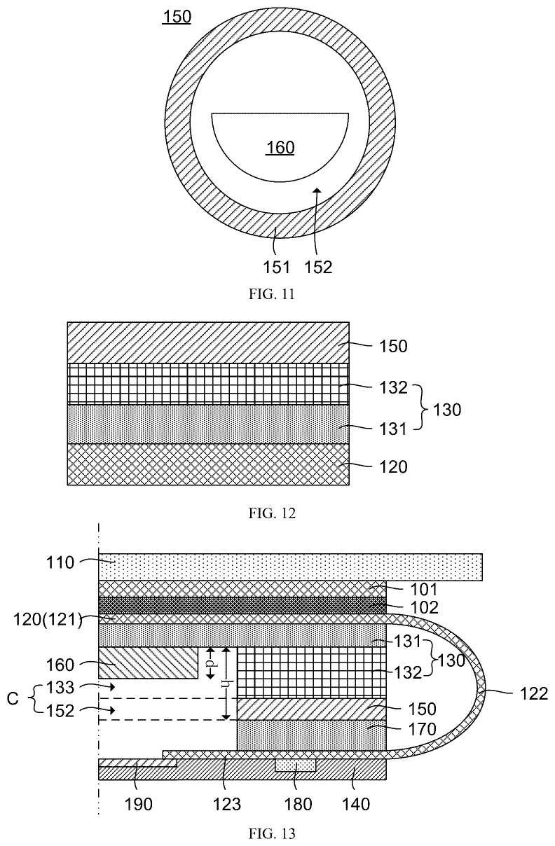

FIG. 10 is a rear view schematically illustrating another electrostatic shielding layer and another NFC module. FIG. 11 is a rear view schematically illustrating another electrostatic shielding layer and another NFC module. For example, as shown in FIG. 10 and FIG. 11, the first hollowed-out region 152 is circular, and the electrostatic shielding region 151 is annular, with the electrostatic shielding region 151 surrounding the first hollowed-out region 152. This can increase the area of the first hollowed-out region 152, thereby reducing the interference and shielding effects of the electrostatic shielding layer 150 on the RF field. Moreover, since the area of the first hollowed-out region 152 is increased, the display module 100 can be compatible with NFC modules 160 of other shapes and sizes.

The electrostatic shielding region 151 can extend along the periphery of the display panel 120. For example, the periphery of the electrostatic shielding region 151 can be flush with the periphery of the display panel 120. Of course, the periphery of the electrostatic shielding region 151 can also be recessed inward from the periphery of the display panel 120 by a certain distance, or it can protrude outward from the periphery of the display panel 120 by a certain distance.

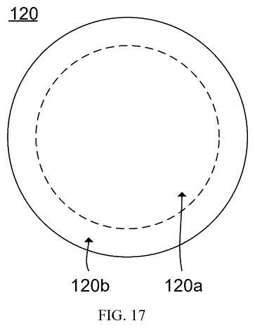

FIG. 17 is a schematic rear view of a display panel. As shown in FIG. 17, the display panel 120 includes a center region 120a and a peripheral region 120b surrounding the center region 120a. The orthogonal projection of the electrostatic shielding region 151 on the display panel 120 at least partially covers the peripheral region 120b.

For example, the orthogonal projection of the electrostatic shielding region 151 on the display panel 120 completely covers the peripheral region 120b.

Since static charges are prone to entering the interior of the display panel 120 along its periphery, the electrostatic shielding region 151 can absorb static charges near the periphery of the display panel 120 by extending along the periphery of the display panel 120, thereby preventing the static charges from entering the interior of the display panel 120 along edges of the display panel 120.

Of course, the structure of the electrostatic shielding layer 150 is not limited to the above structures. For example, in the rear view direction, the electrostatic shielding layer 150 can also be C-shaped.

Referring to FIG. 4, the display module 100 also includes a heat dissipation layer 130 coupled to the backlight side of the display panel 120. The heat dissipation layer 130 is used for absorbing the heat generated during the operation of the display panel 120, thereby reducing the temperature of the display panel 120. Moreover, the heat dissipation layer 130 can also serve to protect the backlight side of the display panel 120.

FIG. 12 is a cross-sectional view of a display module schematically illustrating partial structures. As shown in FIG. 12, the heat dissipation layer 130 can include a thermal conductive layer 131 and an adhesive layer 132. The thermal conductive layer 131 is coupled to the backlight side of the display panel 120, and the adhesive layer 132 is coupled to the side of the thermal conductive layer 131 facing away from the display panel 120.

For example, the material of the thermal conductive layer 131 is PET. For example, the thermal conductive layer 131 is a PET foam layer with a thickness of 60 μm.

For example, the adhesive layer 132 includes a foam layer and a mesh adhesive (Embo) layer. The mesh adhesive layer is adhered to the thermal conductive layer 131, and the foam layer is adhered to the side of the mesh adhesive layer facing away from the thermal conductive layer 131.

In the related art, the heat dissipation layer 130 is susceptible to being squeezed by other modules in the display device, causing the squeezed parts of the heat dissipation layer 130 to become thinner while the unsqueezed parts remain thicker. This results in non-uniform thickness across different regions of the heat dissipation layer 130. When viewing the display module 100 from the light-emitting side, mold marks on the display module 100 are easily noticeable, which affects the user experience.

Referring to FIG. 12, the electrostatic shielding layer 150 can be coupled to the side of the heat dissipation layer 130 facing away from the display panel 120. When the electrostatic shielding layer 150 is squeezed by other modules in the display device, it can distribute the compressive force and then transfer it to the heat dissipation layer 130, making the force more on the heat dissipation layer 130 uniform. This improves the uneven thickness problem of the heat dissipation layer 130 caused by squeezing, thus reducing the mold mark phenomenon. Moreover, when the electrostatic shielding layer 150 is made of a metal material, the hardness of the metal material is usually higher than that of the heat dissipation layer 130, making the heat dissipation layer 130 less likely to deform and further alleviating the mold mark phenomenon.

FIG. 16 is a schematic rear view of the heat dissipation layer. As shown in FIG. 16, the heat dissipation layer 130 can include a first region 130a and a second region 130b surrounding the first region 130a. The first region 130a and the second region 130b are regions of the heat dissipation layer 130. For example, the first region 130a is a circular region located at the center of the heat dissipation layer 130, and the second region 130b is an annular region surrounding the first region 130a. Of course, this disclosure does not limit the shape of the first region 130a and the second region 130b. The first region 130a can also be a polygon such as a rectangle or triangle, or any other irregular shape.

The orthographic projection of the electrostatic shielding layer 150 on the heat dissipation layer 130 is located within the second region 130b. At least part of the orthographic projection of the NFC module 160 on the heat dissipation layer 130 is located within the first region 130a. Since the electrostatic shielding layer 150 is not arranged in the first region 130a, the first region 130a will not interfere with or shield the radio frequency field. As a result, the radio frequency field can pass through the first region 130a and then be received by the NFC module 160. Moreover, the electrostatic shielding layer 150 can absorb static charges, thereby preventing the static charges from entering the interior of the display panel 120 along edges of the display panel, and improving display defects such as screen flickering. When the display device is wirelessly charged through the wireless charging coil, the electrostatic shielding layer 150 can shield the electromagnetic field generated by the wireless charging coil, preventing the display panel 120 from experiencing display defects such as water ripples. That is, the display module 100 of this disclosure improves display defects such as screen flickering and water ripples while ensuring the normal communication of the NFC module 160.

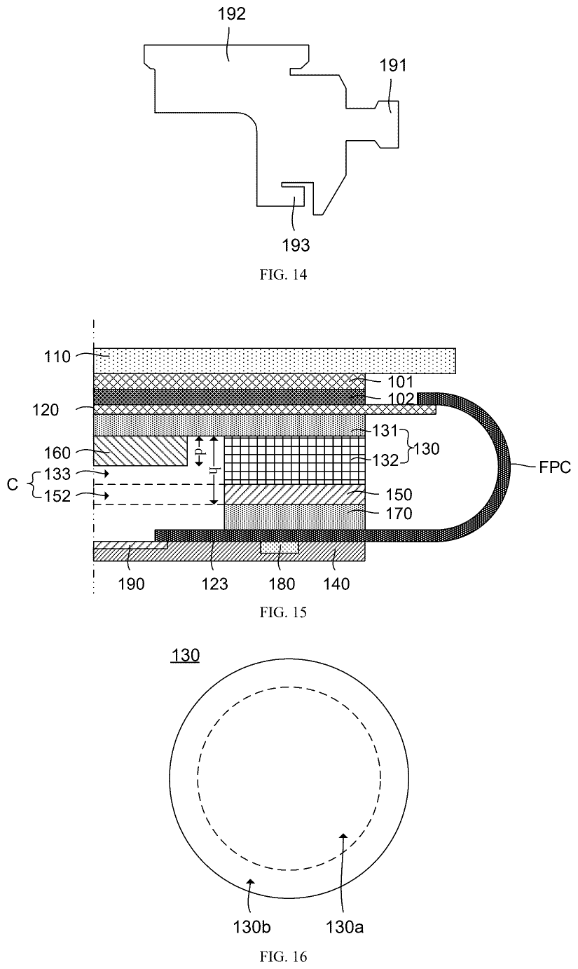

FIG. 13 is a rotated cross-sectional view taken along line A-A in FIG. 3. As shown in FIG. 13, the heat dissipation layer 130 is provided with a groove 133. The groove 133 is arranged opposite to the first hollowed-out region 152, and the groove 133 and the first hollowed-out region 152 enclose an accommodating recess C.

The groove 133 is arranged on the side of the heat dissipation layer 130 facing the electrostatic shielding layer 150. When the heat dissipation layer 130 includes the thermal conductive layer 131 and the adhesive layer 132, the depth of the groove 133 can be less than the thickness of the adhesive layer 132, equal to the thickness of the adhesive layer 132, or greater than the thickness of the adhesive layer 132. The depth of the groove 133 refers to the dimension of the groove 133 in a direction perpendicular to the display panel 120, and the thickness of the adhesive layer 132 refers to the dimension of the adhesive layer 132 in the direction perpendicular to the display panel 120.

When the depth of the groove 133 is less than the thickness of the adhesive layer 132, for example, a part of the adhesive layer 132 can be thinned to form the groove 133. For instance, the adhesive layer 132 includes the foam layer and the mesh adhesive layer, and a part of the foam layer is hollowed out. The hollowed-out region and the mesh adhesive layer form the groove 133.

When the depth of the groove 133 is equal to the thickness of the adhesive layer 132, for example, the adhesive layer 132 includes a second hollowed-out region. The second hollowed-out region is arranged opposite to the first hollowed-out region 152. The second hollowed-out region and the thermal conductive layer 131 enclose the groove 133. The second hollowed-out region is a part of the adhesive layer 132, and the adhesive layer 132 in this region is completely removed. For instance, the adhesive layer 132 includes a foam layer and a mesh adhesive layer. A part of the foam layer is hollowed out, and a part of the mesh adhesive layer is also hollowed out. The hollowed-out regions of the foam layer and the mesh adhesive layer are arranged opposite to each other and together enclose the second hollowed-out region.

When the depth of the groove 133 is less than or equal to the thickness of the adhesive layer 132, no hollowed-out region is provided in the thermal conductive layer 131 or the thermal conductive layer 131 is not thinned, avoiding the heat dissipation effect being affected due to the reduction in the thickness of the thermal conductive layer 131.

When the depth of the groove 133 is greater than the thickness of the adhesive layer 132, for example, the adhesive layer 132 is provided with a second hollowed-out region, and the thermal conductive layer 131 includes a thinned region opposite to the second hollowed-out region. The thickness of the thermal conductive layer 131 in the thinned region is relatively thin. The second hollowed-out region and the thinned region together enclose the groove 133.

At least a part of the structure of the NFC module 160 can be located within the accommodating recess C. On the one hand, the accommodating recess C can limit the position of the NFC module 160 in a direction parallel to the display panel 120. On the other hand, the thickness of the display module 100 can be reduced by providing a part or all of the structure of the NFC module 160 in the accommodating recess C.

The depth h of the accommodating recess C in the direction perpendicular to the display panel 120 can be greater than or equal to the thickness d of the NFC module 160 in the direction perpendicular to the display panel 120. This allows the NFC module 160 to be completely accommodated within the accommodating recess C, thereby further reducing the thickness of the display module 100.

For example, the difference between the depth h of the accommodating recess C and the thickness d of the NFC module 160 can be 0.05 mm to 0.15 mm.

Of course, the depth h of the accommodating recess C in the direction perpendicular to the display panel 120 can also be less than the thickness d of the NFC module 160 in the direction perpendicular to the display panel 120. In this case, partial structures of the NFC module 160 protrude from the accommodating recess C in the direction perpendicular to the display panel 120.

In practical applications, the adhesive layer 1 of the NFC module 160 can be adhered to the thermal conductive layer 131 to secure the NFC module 160.

Referring to FIG. 3, FIG. 4, and FIG. 13, the display module 100 can also include a control board 190. The control board 190 is electrically connected to the display panel 120 to provide image signals to the display panel 120. The control board 190 can also be electrically connected to the NFC module 160 to receive electrical signals from the NFC module 160. The control board 190 can be a main flexible printed circuit (MFPC) including one or more layers of flexible circuit boards. For example, the control board 190 can include two layers of flexible circuit boards, or it can include five layers of flexible circuit boards. In the embodiments of this disclosure, the control board 190 is exemplarily shown as a two-layer flexible circuit board.

FIG. 14 is a schematic structural diagram of the control board. As shown in FIG. 14, the control board 190 can include a connector 191 that is connected to the main board of the display device to achieve electrical connection between the control board 190 and the main board of the display device. The control board 190 can also include a bonding end 192 that is bonded to the display panel 120 to achieve electrical connection between the control board 190 and the display panel 120. The control board 190 can also include a connection end 193 that is electrically connected to the NFC module 160.

The control board 190 can be located on the side of the NFC module 160 facing away from the display panel 120.

For example, the orthogonal projections of the control board 190 and the NFC module 160 on the display panel 120 at least partially overlap with each other. That is, the control board 190 and the accommodating recess C enclose a space, and the NFC module 160 is restricted within this space to prevent the NFC module 160 from shifting and dislodging from the accommodating recess C when subjected to vibrations. For example, the NFC module 160 is located between the thermal conductive layer 131 and the control board 190, thereby allowing the thermal conductive layer 131 and the control board 190 to jointly restrict the position of the NFC module 160 in the direction perpendicular to the display panel 120.

The NFC module 160 can be fixedly connected to the control board 190. On the one hand, the position of the NFC module 160 can be restricted by the control board 190 to prevent the NFC module 160 from disconnecting from the control board 190 when subjected to vibrations. On the other hand, since the NFC module 160 and the control board 190 are fixedly connected, during the assembly of the display module 100, the NFC module 160 and the control board 190 can be assembled as a single unit and then connected to the display panel 120. Compared to connecting the NFC module 160 and the control board 190 to the display panel 120 separately, this approach reduces the number of assembly steps and lowers the assembly difficulty.

For example, the connection part 161 of the NFC module 160 is soldered to the connection end 193 of the control board 190. For instance, the connection part 161 of the NFC module 160 and the connection end 193 of the control board 190 are soldered in advance to form an integrated structure before entering the assembly process of the display module 100. That is, the NFC module 160 and the control board 190 are supplied as an integrated unit.

The side of the control board 190 facing the display panel 120 can be in contact with the electrostatic shielding layer 150, allowing the static charges absorbed by the electrostatic shielding layer 150 to be discharged through the control board 190.

For example, a part of the orthogonal projection of the control board 190 on the electrostatic shielding layer 150 is located within the electrostatic shielding region 151 to ensure contact between the control board 190 and the electrostatic shielding region 151. A part of the orthogonal projection of the control board 190 on the electrostatic shielding layer 150 is located within the first hollowed-out region 152 to restrict the position of the NFC module 160.

In the direction perpendicular to the display panel 120, a gap may exist between the NFC module 160 and the control board 190. When the NFC module 160 is subjected to vibrations, it can easily shift relative to the control board 190, leading to disconnection between the NFC module 160 and the control board 190 and causing the NFC module 160 to malfunction. To enhance the anti-vibration performance of the display device, a buffer layer can be provided between the NFC module 160 and the control board 190. The buffer layer is bonded to the NFC module 160 and the control board 190, so that the NFC module 160, the buffer layer and the control board 190 are connected to form an integrated structure, thereby preventing relative displacement.

For example, the buffer layer is an adhesive filled between the NFC module 160 and the control board 190.

Referring to FIG. 13, FIG. 13 shows a partial cross-sectional view of the display module 100 when the display panel 120 is a flexible display panel. When the display panel 120 is a flexible display panel, it can include a flat portion 121, a bending portion 122, and a bonding portion 123 that are connected in sequence.

The flat portion 121 can include a display region and a non-display region. The display region can have a plurality of sub-pixels, a plurality of data lines, and a plurality of gate lines. The non-display region can have a scan drive circuit electrically connected to the gate lines. The bonding end 192 is provided on the bonding portion 123, allows the bonding end 192 of the control board 190 to be bonded to the bonding portion 123 through the bonding end 192. The bending portion 122 connects the flat portion 121 and the bonding portion 123, and the bonding portion 123 is bent to the backlight side of the flat portion 121 through the bending portion 122 to reduce the bezel width of the display device.

The heat dissipation layer 130 and the electrostatic shielding layer 150 are located between the flat portion 121 and the bonding portion 123, and the heat dissipation layer 130 is connected to the backlight side of the flat portion 121 and the electrostatic shielding layer 150 is connected to the side of the heat dissipation layer 130 facing away from the flat portion 121.

The display module 100 can also include a spacer 170 located between the bonding portion 123 and the electrostatic shielding layer 150. One side of the spacer 170 is connected to the bonding portion 123, and the other side is connected to the electrostatic shielding layer 150, so as to secure the bonding portion 123 and prevent the bonding portion 123 from rebounding through the bending portion 122.

For example, both sides of the spacer 170 is provided with adhesive to bond the spacer 170 to the bonding portion 123 and the electrostatic shielding layer 150. The thickness of the adhesive can be 10 μm.

For example, the material of the spacer 170 is PET. For instance, the spacer 170 is a PET foam with a thickness of 50 μm.

FIG. 15 is a cross-sectional view of another display module schematically illustrating partial structures. As shown in FIG. 15, the display panel 120 can also be a rigid display panel. In this case, the display module 100 also includes a flexible printed circuit (FPC). One end of the FPC is bonded to the display panel 120, and the other end is bent to the backlight side of the display panel 120 and electrically connected to the control board 190. One side of the spacer 170 is connected to the FPC, and the other side of the spacer 170 is connected to the electrostatic shielding layer 150.

Referring to FIG. 13 and FIG. 15, the display module 100 also includes a drive chip 180. The drive chip 180 can be electrically connected to the data lines and the scan drive circuit to provide data signals to the data lines and scan signals to the scan drive circuit. When the display panel 120 is a flexible display panel, the drive chip 180 can be bonded to the side of the bonding portion 123 facing away from the flat portion 121. When the display panel 120 is a rigid display panel, the drive chip 180 can be bonded to the FPC (COF packaging) or the display panel 120 (COG packaging).

Referring to FIG. 13 and FIG. 15, the display module 100 can also include a conductive layer 140 that covers the drive chip 180. The conductive layer 140 can be made of conductive materials with ductility. For example, the conductive layer 140 can be conductive fabric, copper foil, gold foil, lithium, etc. When the conductive layer 140 is conductive fabric, its thickness can be 60 μm.

The conductive layer 140 covers the driver chip 180 to prevent the driver chip 180 from being affected by electrostatic interference. Additionally, the conductive layer 140 isolates the driver chip 180 from the external environment, protecting it from corrosion.

For example, the conductive layer 140 can also cover the side of the control board 190 facing away from the display panel 120. This prevents the control board 190 from being affected by electrostatic interference, and isolates the control board 190 from the external environment to prevent corrosion of the drive chip 180.

Embodiments of the present disclosure provide a display module and a display device. An electrostatic shielding layer and an NFC module are arranged on the backlight side of the display panel. The electrostatic shielding layer includes a first hollowed-out region, and the orthogonal projection of the first hollowed-out region and the orthogonal projection of the NFC module on the display panel at least partially overlap with each other. Since the conductive material has been removed from the first hollowed-out region, the first hollowed-out region will not interfere with or shield the RF field, allowing the RF field to pass through the first hollowed-out region and be received by the NFC module. Moreover, the electrostatic shielding layer can absorb static charges, thereby preventing them from entering the interior of the display panel along edges of the display panel and improving display defects such as screen flickering. When the display device is wirelessly charged through the wireless charging coil, the electrostatic shielding layer can shield the electromagnetic field generated by the wireless charging coil, preventing the display panel from experiencing display defects such as water ripples. That is, the display module and display device of this disclosure improve display defects such as screen flickering and water ripples while ensuring the normal communication of the NFC module.

The above descriptions are merely specific implementations of this disclosure, but the scope of protection of this disclosure is not limited to these. Any changes or substitutions that can be easily conceived by those skilled in the art within the technical scope disclosed in this disclosure should be covered within the scope of protection of this disclosure. Therefore, the scope of protection of this disclosure should be defined by the appended claims.

1. A display module, comprising:
a display panel comprising a light-emitting side and a backlight side arranged opposite to each other;
a Near Field Communication (NFC) module located on the backlight side of the display panel; and
an electrostatic shielding layer located on the backlight side of the display panel, wherein the electrostatic shielding layer comprises a first hollowed-out region, an orthogonal projection of the first hollowed-out region on the display panel and an orthogonal projection of the NFC module on the display panel at least partially overlap with each other.

2. The display module according to claim 1, wherein the electrostatic shielding layer further comprises an electrostatic shielding region surrounding the first hollowed-out region, the orthogonal projection of the NFC module on the display panel is within the orthogonal projection of the first hollowed-out region on the display panel.

3. The display module according to claim 2, wherein the display panel comprises a center region and a peripheral region surrounding the center region, an orthogonal projection of the electrostatic shielding region on the display panel at least partially covers the peripheral region.

4. The display module according to claim 1, further comprising a heat dissipation layer coupled to the backlight side of the display panel, and the electrostatic shielding layer is coupled to a side of the heat dissipation layer facing away from the display panel.

5. The display module according to claim 4, wherein the heat dissipation layer is provided with a groove, the groove is arranged opposite to the first hollowed-out region, and the groove and the first hollowed-out region enclose an accommodating recess, at least a part of structures of the NFC module is located within the accommodating recess.

6. The display module according to claim 5, wherein a depth of the accommodating recess in a direction perpendicular to the display panel is greater than or equal to a thickness of the NFC module in the direction perpendicular to the display panel.

7. The display module according to claim 6, wherein the electrostatic shielding layer is located on a side of the NFC module facing away from the display panel.

8. The display module according to claim 5, wherein the heat dissipation layer comprises a thermal conductive layer and an adhesive layer stacked in sequence in a direction facing away from the display panel, the adhesive layer comprises a second hollowed-out region, the second hollowed-out region and the thermal conductive layer enclose the groove.

9. The display module according to claim 1, further comprising a control board, the control board is located on a side of the NFC module facing away from the display panel, and the NFC module is fixedly connected to the control board.

10. The display module according to claim 9, wherein a side of the control board facing the display panel is in contact with the electrostatic shielding layer.

11. The display module according to claim 9, wherein a buffer layer is provided between the NFC module and the control board, the buffer layer is bonded to both the NFC module and the control board.

12. The display module according to claim 4, wherein the display panel is a flexible display panel comprising a flat portion, a bending portion, and a bonding portion connected in sequence, the bonding portion is bent to the backlight side of the flat portion through the bending portion, the heat dissipation layer is coupled to the backlight side of the flat portion, the electrostatic shielding layer is connected to a side of the heat dissipation layer facing away from the flat portion;
the display module further comprises a spacer located between the bonding portion and the electrostatic shielding layer.

13. The display module according to claim 12, further comprising a drive chip and a conductive layer, the drive chip is bonded to a side of the bonding portion facing away from the flat portion, the conductive layer covers the drive chip.

14. A display module, comprising:
a display panel comprising a light-emitting side and a backlight side arranged opposite to each other;
a heat dissipation layer coupled to the backlight side of the display panel, the heat dissipation layer comprises a first region and a second region surrounding the first region;
an electrostatic shielding layer located on a side of the heat dissipation layer facing away from the display panel, and an orthogonal projection of the electrostatic shielding layer on the heat dissipation layer is within the second region; and
a Near Field Communication (NFC) module, wherein at least a part of an orthogonal projection of the NFC module on the heat dissipation layer is within the first region.

15. A display device, comprising the display module according to claim 1.

16. A display device, comprising the display module according to claim 14.
